(19) United States
(12) Patent Application Publication
(10) Pub. No.: US 2025/0386734 A1
(43) Pub. Date: Dec. 18, 2025

(54) METHOD FOR FABRICATING MAGNETORESISTIVE RANDOM ACCESS MEMORY

(71) Applicant: UNITED MICROELECTRONICS CORP., Hsin-Chu City (TW)

(72) Inventors: Ching-Hua Hsu, Kaohsiung City (TW); Chau-Chung Hou, Kaohsiung City (TW); Hui-Lin Wang, Taipei City (TW)

(73) Assignee: UNITED MICROELECTRONICS CORP., Hsin-Chu City (TW)

(21) Appl. No.: 18/788,046

(22) Filed: Jul. 29, 2024

(30) Foreign Application Priority Data
Jun. 18, 2024 (TW) 113122456

(51) Int. Cl. H10N 50/01; G11C 11/16; H10B 61/00; H10N 50/10; H10N 50/80

(52) U.S. Cl. CPC H10N 50/01; G11C 11/161; H10B 61/00; H10N 50/10; H10N 50/80

(57) ABSTRACT

A method for fabricating a magnetoresistive random access memory (MRAM) device includes the steps of forming a magnetic tunneling junction (MTJ) on a substrate, forming a dielectric layer on the MTJ, performing a first etching process to form a first trench in the dielectric layer, and performing a second etching process to form a second trench in the dielectric layer. Preferably, a bottom surface of the second trench is lower than a bottom surface of the first trench, a width of the second trench is less than a width of the first trench, and the first trench and the second trench together form a step profile.

### BACKGROUND OF THE INVENTION

### 1. Field of the Invention

The invention relates to a method for fabricating semiconductor device, and more particularly to a method for fabricating magnetoresistive random access memory (MRAM).

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes the steps of forming a magnetic tunneling junction (MTJ) on a substrate, forming a dielectric layer on the MTJ, performing a first etching process to form a first trench in the dielectric layer, and performing a second etching process to form a second trench in the dielectric layer. Preferably, a bottom surface of the second trench is lower than a bottom surface of the first trench, a width of the second trench is less than a width of the first trench, and the first trench and the second trench together form a step profile.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a MRAM device according to an embodiment of the present invention.

FIGS. 10-11 illustrate a method for fabricating a MRAM device according to an embodiment of the present invention.

### DETAILED DESCRIPTION

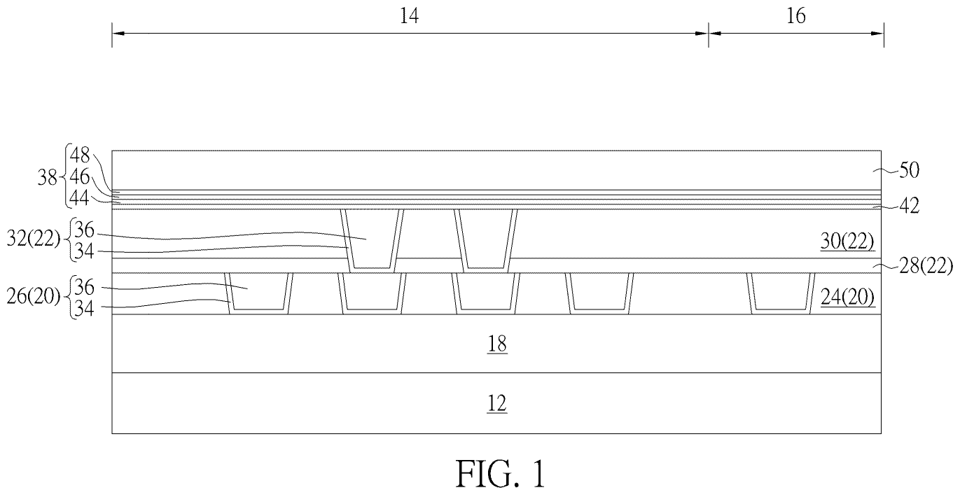

Referring to FIGS. 1-9, FIGS. 1-9 illustrate a method for fabricating a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region 16 are defined on the substrate 12.

Active devices such as metal-oxide semiconductor (MOS) transistors, passive devices, conductive layers, and interlayer dielectric (ILD) layer 18 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 18 could be formed on the substrate 12 to cover the MOS transistors, and a plurality of contact plugs could be formed in the ILD layer 18 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 20, 22 are sequentially formed on the ILD layer 18 on the MRAM region 14 and the logic region 16 to electrically connect the aforementioned contact plugs, in which the metal interconnect structure 20 includes an inter-metal dielectric (IMD) layer 24 and metal interconnections 26 embedded in the IMD layer 24, and the metal interconnect structure 22 includes a stop layer 28, an IMD layer 30, and metal interconnections 32 embedded in the stop layer 28 and the IMD layer 30.

In this embodiment, each of the metal interconnections 26 from the metal interconnect structure 20 preferably includes a trench conductor and the metal interconnection 32 from the metal interconnect structure 22 on the MRAM region 14 includes a via conductor. Preferably, each of the metal interconnections 26, 32 from the metal interconnect structures 20, 22 could be embedded within the IMD layers 24, 30 and/or stop layer 28 according to a single damascene process or dual damascene process. For instance, each of the metal interconnections 26, 32 could further includes a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 are preferably made of copper, the IMD layers 24, 30 are preferably made of silicon oxide, and the stop layers 28 is preferably made of nitrogen doped carbide (NDC), silicon nitride, silicon carbon nitride (SiCN), or combination thereof.

Next, a bottom electrode 42, a MTJ stack 38 or stack structure, a top electrode 50, and a patterned mask (not shown) are formed on the metal interconnect structure 22. In this embodiment, the formation of the MTJ stack 38 could be accomplished by sequentially depositing a pinned layer 44, a barrier layer 46, and a free layer 48 on the bottom electrode 42. In this embodiment, the bottom electrode layer 42 and the top electrode layer 50 are preferably made of conductive material including but not limited to for example Ta, Pt, Cu, Au, Al, or combination thereof. The pinned layer 44 could be made of ferromagnetic material including but not limited to for example iron, cobalt, nickel, or alloys thereof such as cobalt-iron-boron (CoFeB) or cobalt-iron (CoFe). Moreover, the pinned layer 44 could also be made of antiferromagnetic (AFM) material including but not limited to for example ferromanganese (FeMn), platinum manganese (PtMn), iridium manganese (IrMn), nickel oxide (NiO), or combination thereof, in which the pinned layer 44 is formed to fix or limit the direction of magnetic moment of adjacent layers. The barrier layer 46 could be made of insulating material including but not limited to for example oxides such as aluminum oxide (AlOₓ) or magnesium oxide (MgO). The free layer 48 could be made of ferromagnetic material including but not limited to for example iron, cobalt, nickel, or alloys thereof such as cobalt-iron-boron (CoFeB), in which the magnetized direction of the free layer 48 could be altered freely depending on the influence of outside magnetic field.

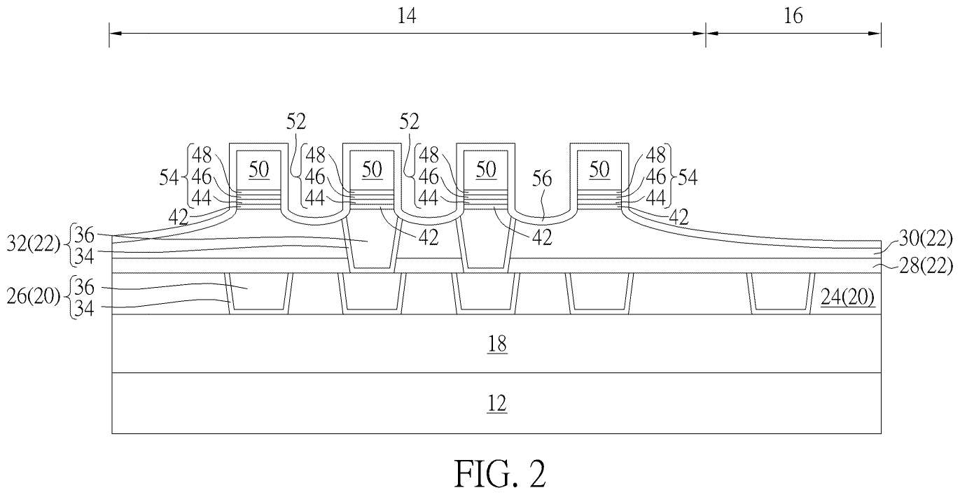

Next, as shown in FIG. 2, one or more etching process is conducted by using the patterned mask as mask to remove part of the top electrode 50, part of the MTJ stack 38, part of the bottom electrode 42, and part of the IMD layer 30 to form MTJs 52, 54 on the MRAM region 14, in which metal interconnections 32 are disposed under part of the MTJs such as the MTJs 52 while no metal interconnections are disposed under dummy MTJs such as the MTJs 54. It should be noted that a reactive ion etching (RIE) and/or an ion beam etching (IBE) process is conducted to remove the top electrode 50, MTJ stack 38, bottom electrode 42, and the IMD layer 38 in this embodiment for forming the MTJs 52, 54. Due to the characteristics of the IBE process, the top surface of the remaining IMD layer 30 is slightly lower than the top surface of the metal interconnections 32 after the IBE process and the top surface of the IMD layer 30 also reveals a curve or an arc. It should also be noted that as the IBE process is conducted to remove part of the IMD layer 30, part of the metal interconnection 32 is removed at the same time to form inclined sidewalls or curvy sidewalls on the surface of the metal interconnection 32 immediately adjacent to the MTJs 52, 54. Next, a cap layer 56 is formed on the MTJs 52, 54 while covering the surface of the IMD layer 30. In this embodiment, the cap layer 56 preferably includes silicon nitride, but could also include other dielectric material including but not limited to for example silicon oxide, silicon oxynitride (SiON), or silicon carbon nitride (SiCN).

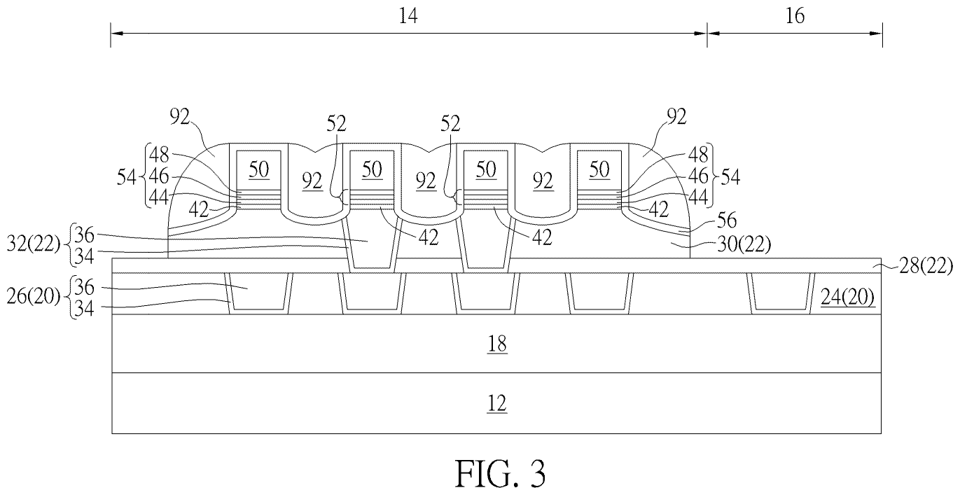

Next, as shown in FIG. 3, an atomic layer deposition (ALD) process is conducted to form a dielectric layer 92 on the MTJs 52, 54, and an etching back process is conducted to remove part of the dielectric layer 92, part of the cap layer 56, and part of the IMD layer 30 on the MRAM region 14 and logic region 16 so that the remaining dielectric layer 92 is only disposed around the MTJs 52, 54 on the MRAM region 14 as sidewalls of the dielectric layer 92 are aligned with sidewalls of the IMD layer 30 underneath.

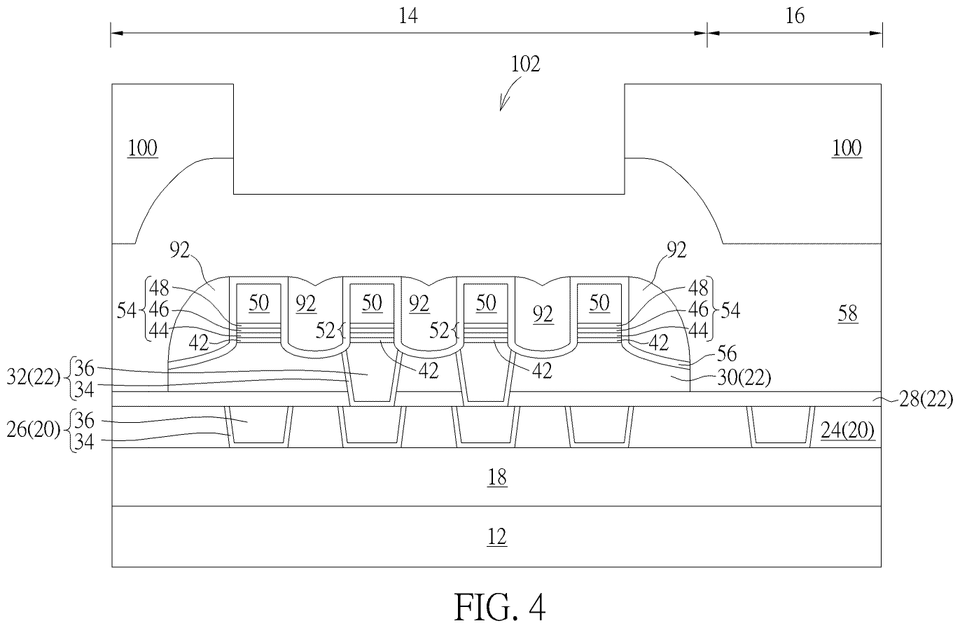

Next, as shown in FIG. 4, an IMD layer 58 is formed on the MRAM region 14 and logic region 16 to cover the dielectric layer 92. It should be noted that since a significant height difference is present between the dielectric layer 92 and adjacent areas on the MRAM region 14, after the IMD layer 58 is formed, the top surface of the IMD layer 58 directly on top of the dielectric layer 92 would be slightly higher than the top surface of the IMD layer 58 adjacent to two sides of the dielectric layer 92.

Next, a patterned mask 100 such as a patterned resist is formed to cover part of the IMD layer 58 on the MRAM region 14 and logic region 16 and expose the surface of the IMD layer 58 directly on top of the dielectric layer 92, and then an etching process is conducted by using the patterned mask 100 as mask to remove part of the IMD layer 58 directly on top of the dielectric layer 92 for forming a first trench 102 in the IMD layer 58. Preferably, the width of the first trench 102 is less than the overall width of the dielectric layer 92 on the MRAM region 14 and the bottom surface of the first trench 102 is slightly higher than the top surface of the IMD layer 58 adjacent two sides of the dielectric layer 92. Viewing from another perspective, the etching process conducted at this stage preferably shapes the IMD layer 58 directly on top of the dielectric layer 92 into a substantially U-shape profile. In this embodiment, the IMD layer 92 preferably includes silicon oxide while the IMD layer 58 preferably include an ultra low-k (ULK) dielectric layer including but not limited to for example porous material or silicon oxycarbide (SiOC) or carbon doped silicon oxide (SiOCH).

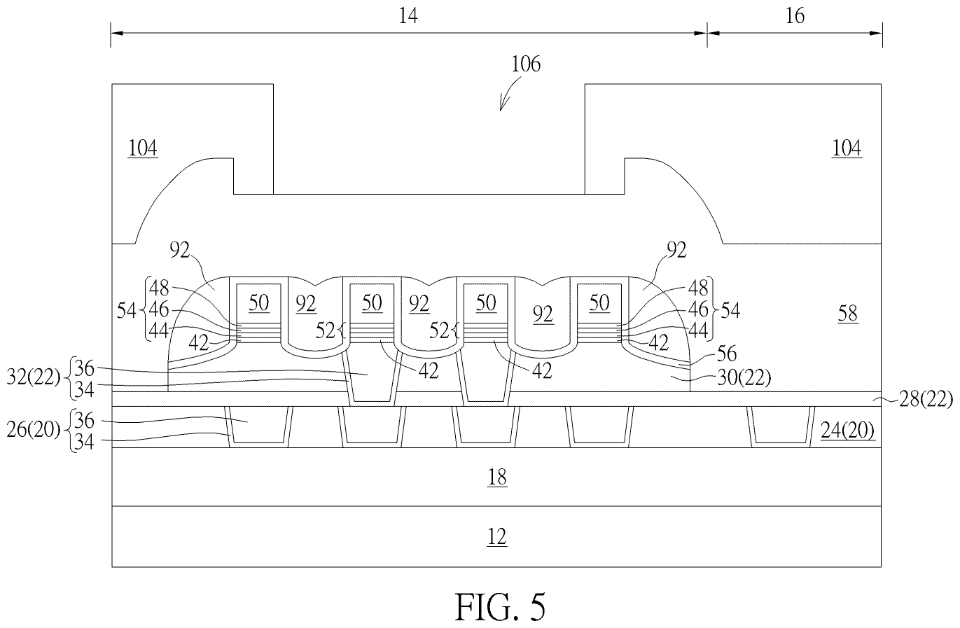

Next, as shown in FIG. 5, after removing the aforementioned patterned mask 100, another patterned mask 104 is formed on the MRAM region 14 and logic region 16, in which the patterned mask 104 covers part of the first trench 102 on the MRAM region 14 and all of the logic region 16, the patterned mask 104 includes an opening 106 exposing the surface of the IMD layer 58 closer to the central portion of the first trench 102, and the width of the opening 106 is less than the width of the first trench 102 or the width of opening formed during formation of the patterned mask 100.

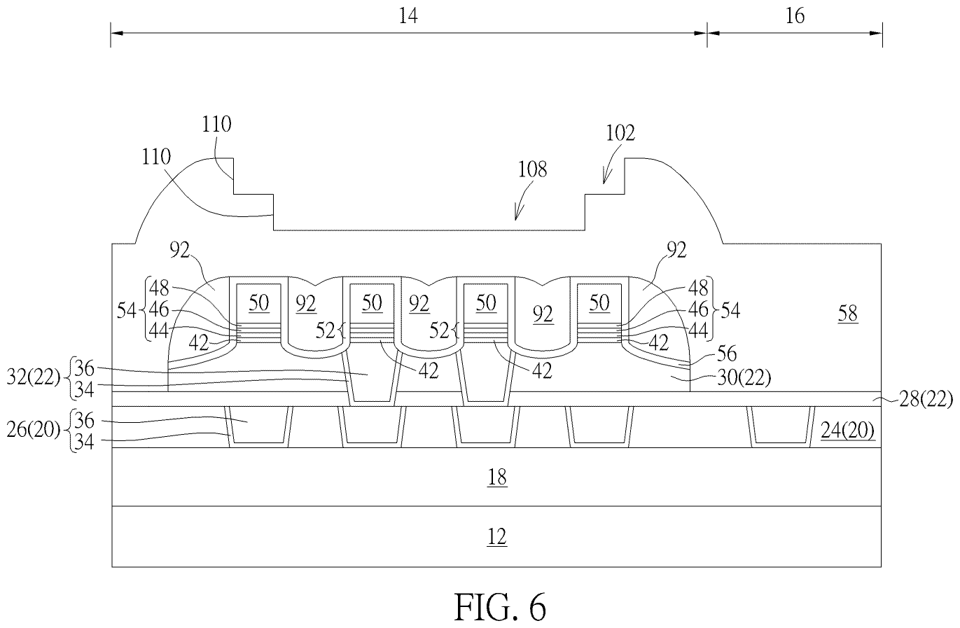

Next, as shown in FIG. 6, an etching process is conducted by using the patterned mask 104 as mask to remove part of the IMD layer 58 directly on top of the dielectric layer 92 for forming a second trench 108. Preferably, the bottom surface of the second trench 108 is lower than the bottom surface of the first trench 102, the width of the second trench 108 is less than the width of the first trench 102, and the first trench 102 and the second trench 108 altogether form a plurality of steps 110 or step portions. Specifically, the second etching process conducted at this stage not only extends the depth of the first trench 102 further downward to form a narrower and deeper second trench 108, but also shapes the IMD layer 58 adjacent to two sides of the two trenches 102, 108 into jagged or serrated profiles with two step portions 110, in which the bottom surface of the second trench 108 could be lower than, even with, or higher than the top surface of the IMD layer 58 adjacent to two sides of the step portions 110.

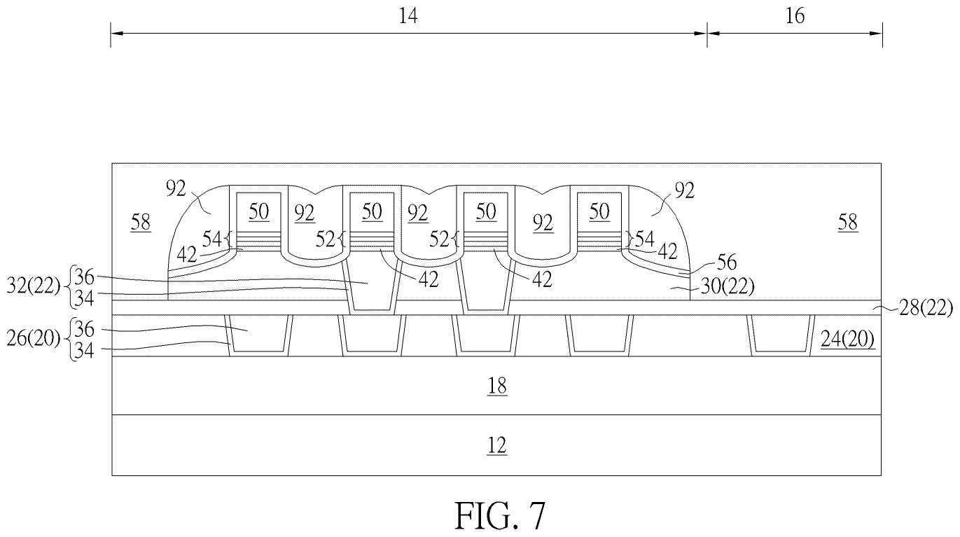

Next, as shown in FIG. 7, a planarizing process such as chemical mechanical polishing (CMP) process is conducted to remove all of the steps 110 or protruding portions of the IMD layer 58 so that the top surface of the remaining IMD layer 58 on the MRAM region 14 and logic region 16 has completely planar surface as the top surface of the IMD layer 58 on the MRAM region 14 is even with the top surface of the IMD layer 58 on the logic region 16.

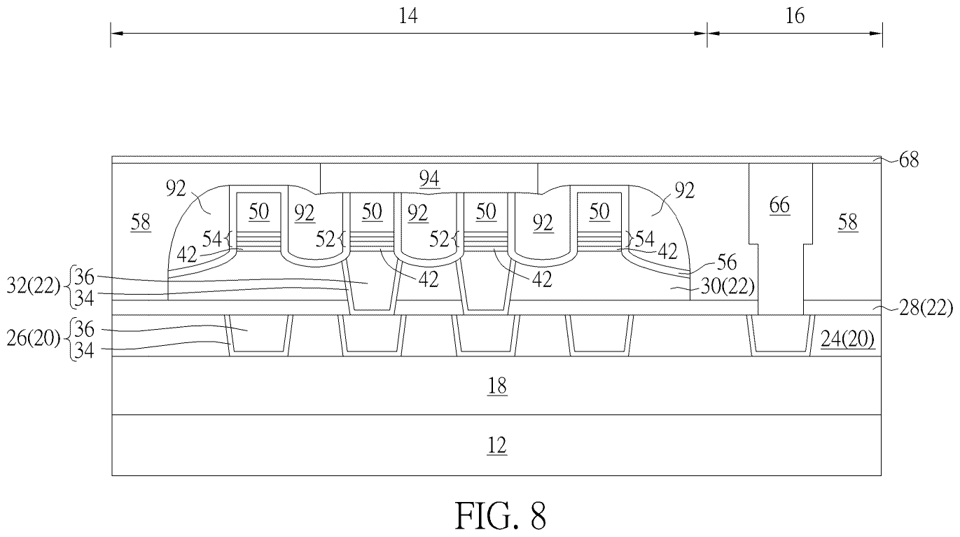

Next, as shown in FIG. 8, a pattern transfer process is conducted by using a patterned mask (not shown) to remove part of the IMD layer 58, part of the dielectric layer 92, and part of the cap layer 56 on the MRAM region 14 to form a contact hole (not shown) exposing the top electrodes 50 underneath, and conductive materials are deposited into the contact hole afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact hole, and a planarizing process such as CMP could be conducted to remove part of the conductive materials including the aforementioned barrier layer and metal layer to form a metal interconnection 94 in the contact hole electrically connecting the MTJs 52 while the adjacent dummy MTJs 54 are not connected whatsoever.

Next, another pattern transfer process is conducted by using a patterned mask (not shown) to remove part of the IMD layer 58, part of the IMD layer 30, and part of the stop layer 28 on the logic region 16 to form a contact hole (not shown) exposing the metal interconnection 26 underneath and conductive materials are deposited into the contact hole afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact hole, and a planarizing process such as CMP could be conducted to remove part of the conductive materials including the aforementioned barrier layer and metal layer to form a metal interconnection 66 in the contact hole electrically connecting the metal interconnection 26. Next, a stop layer 68 is formed on the IMD layer 58 and metal interconnections 66, 94, in which the stop layer 68 could include silicon oxide, silicon nitride, or SiCN.

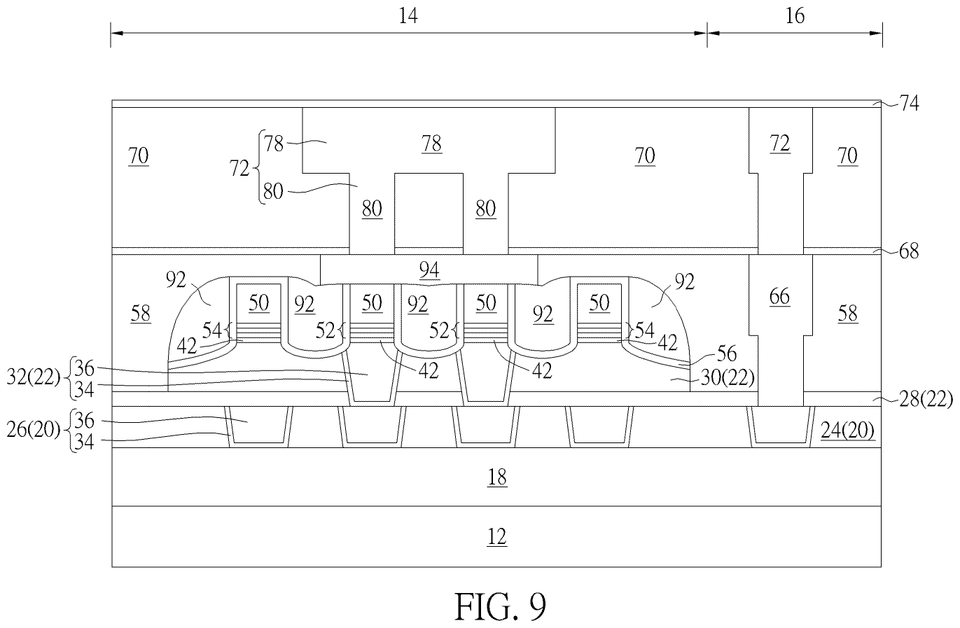

Next, as shown in FIG. 9, an IMD layer 70 is formed on the stop layer 68, and one or more photo-etching process is conducted to remove part of the IMD layer 70 and part of the stop layer 68 on the MRAM region 14 and logic region 16 to form contact holes (not shown). Next, conductive materials are deposited into each of the contact holes and a planarizing process such as CMP is conducted to form metal interconnections 72 connecting the MTJs 52, 54 and metal interconnection 66 underneath, in which the metal interconnection 72 on the MRAM region 14 directly contacts the metal interconnection 94 underneath while the metal interconnection 72 on the logic region 16 directly contacts the metal interconnection 66 on the lower level. Next, another stop layer 74 is formed on the IMD layer 70 to cover the metal interconnections 72. Similar to the embodiment shown in FIG. 6, the metal interconnection 72 disposed on the MRAM region 14 further includes a trench conductor 78 and two via conductors 80 connected to the metal interconnection 94 underneath.

In this embodiment, the stop layers 68 and 74 could be made of same or different materials, in which the two layers 68, 74 could all include nitrogen doped carbide (NDC), silicon nitride, silicon carbon nitride (SiCN), or combination thereof. Similar to the metal interconnections formed previously, each of the metal interconnections 72 could be formed in the IMD layer 70 through a single damascene or dual damascene process. For instance, each of the metal interconnections 72 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. This completes the fabrication of a semiconductor device according to an embodiment of the present invention.

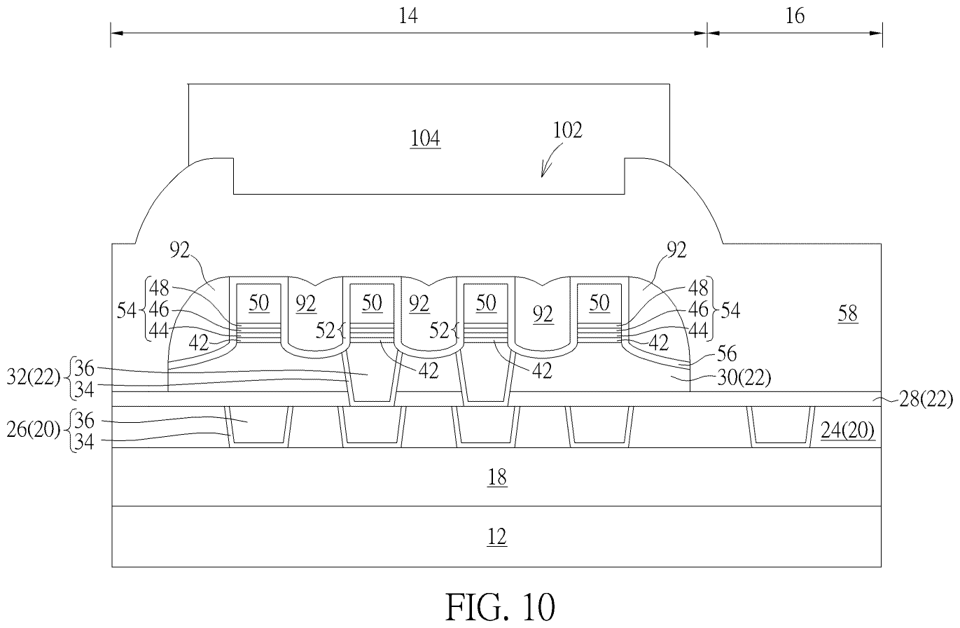

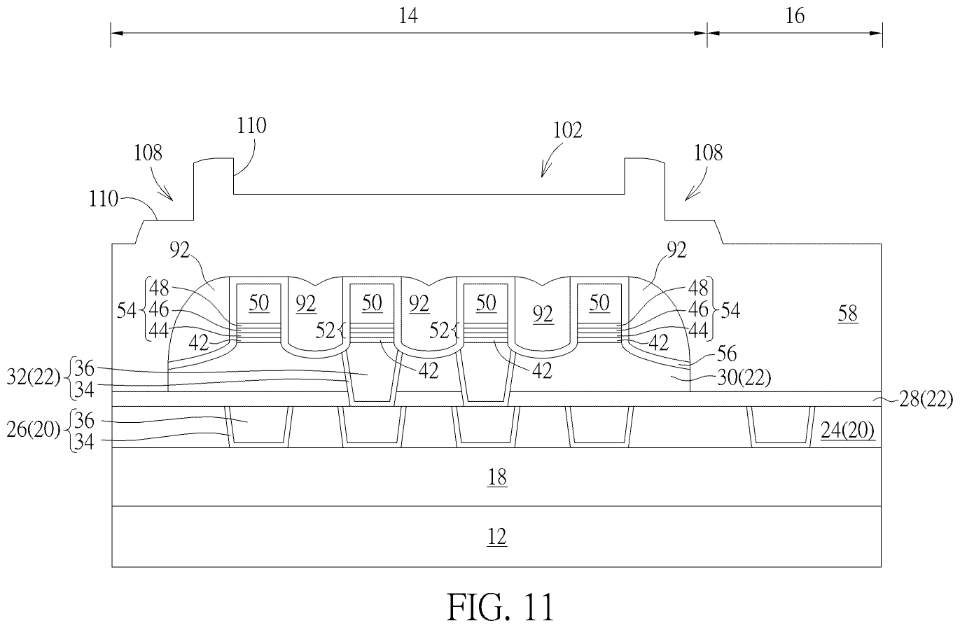

Referring to FIGS. 10-11, FIGS. 10-11 illustrate a method for fabricating a MRAM device according to an embodiment of the present invention. As shown in FIG. 10, it would be desirable to follow the process conducted in FIG. 4 by first using a patterned mask 100 to remove part of the IMD layer 58 directly above the dielectric layer 92 for forming a first trench 102, and then forming another patterned mask 104 directly on the first trench 102 after the patterned mask 100 is removed. It should be noted that in contrast to the patterned mask 104 shown in FIG. 5 is disposed to cover part of the first trench 102 on the MRAM region 14 and all of the logic region 16, the patterned mask 104 formed in this embodiment preferably covers the entire first trench 102 and exposing the IMD layer 58 surface around the first trench 102.

Next, as shown in FIG. 11, an etching process is conducted by using the patterned mask 104 as mask to remove part of the IMD layer 48 adjacent to two sides of the first trench 102 for forming a second trench 108, in which each of the first trench 102 and the second trench 108 forms step portions 110 adjacent to two sides of the protruding IMD layer 58. In other words, in contrast to all the steps 110 are formed adjacent to the same side such as inner side of the protruding IMD layer 58 as shown in FIG. 6, the steps 110 in this embodiment are formed adjacent to both inner side (such as the side closer to the center of the first trench 102) and outer side (such as the side away from the center of the first trench 102) of the protruding IMD layer 58 respectively. Despite the bottom surface of the second trench 108 on the outer side is slightly lower than the bottom surface of the first trench 102 on the inner side, according to other embodiment of the present invention, the first trench 102 and the second trench 108 could also have same or different depths depending on the demand of the product. For instance, the bottom surface of the first trench 102 could be lower than, even with, or higher than the bottom surface of the second trench 108, which are all within the scope of the present invention. Next, steps conducted in FIG. 7 could be carried out by performing a planarizing process such as CMP to remove all the steps 110 or protruding portions formed from the IMD layer 58 so that the top surface of the remaining IMD layer 58 on the MRAM region 14 and logic region 16 could have a completely planar surface. Next, steps conducted in FIGS. 8-9 are carried out to form IMD layers and metal interconnections in the later process.

Overall, the present invention first forms a plurality of MTJs on the MRAM region, forms a dielectric layer 92 around the MTJs, and then forms an IMD layer 58 on the dielectric layer 92. Since a significant height difference is present between the dielectric layer 92 and adjacent areas on the MRAM region 14, after the IMD layer 58 is formed, the top surface of the IMD layer 58 directly on top of the dielectric layer 92 would be slightly higher than the top surface of the IMD layer 58 adjacent to two sides of the dielectric layer 92 without having any dielectric layer 92. Next, more than one photo-etching process is conducted by using patterned masks to remove part of the IMD layer on different stages to form a first trench 102 and a second trench 108 in the IMD layer, in which the height difference between the two trenches 102, 108 altogether forms steps 110 or step portions on the IMD layer. Next, a planarizing process is conducted to remove all of the steps 110 so that the IMD layer 58 on both MRAM region 14 and logic region 16 has a completely planar surface.

It should be noted that even though two photo-etching processes were conducted sequentially to remove part of the IMD layer to form trenches with different depths as shown in FIGS. 4-6, according to other embodiment of the present invention, it would also be desirable to repeat the steps of forming the first trench 102 and second trench 108 after the second trench 108 is formed to form additional third trench, fourth trench, and even fifth trench or more in the IMD layer, in which the width of the trench formed afterwards is less than the width of the trench formed previously while the depth of the trench formed afterwards is also greater than the depth of the trench formed previously. In other words, after the IMD layer is formed it would be desirable to conduct multiple such as two, three, or even four or more photo-etching processes to remove part of the IMD layer at separate stages for forming multiple trenches, in which the edges of the trenches preferably form serrated or jagged profiles such as the step portions 110 in the IMD layer as the quantity of the step portions could be adjusted depending on the number of photo-etching process conducted or the number of the trenches formed. According to a preferred embodiment of the present invention, the formation of the step portions facilitates release of the stress generated during planarization of the IMD layer afterwards, which not only reduces the duration for conducting the planarizing process but also improves the smoothness of the IMD layer surface in the end.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a magnetoresistive random access memory (MRAM) device, comprising:
forming a magnetic tunneling junction (MTJ) on a substrate;
forming a first inter-metal dielectric (IMD) layer on the MTJ;
performing a first etching process to form a first trench in the first IMD layer; and
performing a second etching process to form a second trench in the first IMD layer.

2. The method of claim 1, further comprising:
forming a second IMD layer on the substrate;
forming a metal interconnection in the second IMD layer;
forming the MTJ on the metal interconnection;
forming a dielectric layer around the MTJ; and
forming the first IMD layer on the dielectric layer.

3. The method of claim 1, wherein a bottom surface of the second trench is lower than a bottom surface of the first trench.

4. The method of claim 1, wherein a width of the second trench is less than a width of the first trench.

5. The method of claim 1, wherein the first trench and the second trench comprise a step profile.

6. The method of claim 1, further comprising planarizing the first IMD layer after performing the second etching process.

7. The method of claim 1, wherein the first IMD layer comprises an ultra low-k (ULK) dielectric layer.
